(19) United States
(12) Patent Application Publication
(10) Pub. No.: US 2025/0189302 A1
(43) Pub. Date: Jun. 12, 2025

(54) METHODS OF ESTIMATING LINE WIDTH AND SYSTEMS THEREOF

(71) Applicant: Tokyo Electron Limited, Tokyo (JP)

(72) Inventor: Hoyoung Kang, Albany, NY (US)

(21) Appl. No.: 18/532,585

(22) Filed: Dec. 7, 2023

(51) Int. Cl. G01B 11/02; G03F 7/20

(52) U.S. Cl. CPC G01B 11/02; G03F 7/2002

(57) ABSTRACT

A method for estimating line width of a patterned layer of a substrate includes generating a light beam with a light spectrum including a plurality of wavenumbers, and exposing the patterned layer of a substrate to the light beam to form a first illuminated area. The method includes measuring a first spectrum of the first illuminated area using a light detector, the first spectrum including a first variation in light intensity with a wavenumber of the light beam received at the light detector. The method includes determining a first spectrum area by integrating the first variation in light intensity over a range of the plurality of wavenumbers, the range of the plurality of wavenumbers being selected to match an absorption spectrum of the material of the patterned layer. And the method further includes determining the line width of the patterned layer based on the first spectrum area.

### TECHNICAL FIELD

The present invention relates generally to the field of semiconductor manufacturing, and, in particular embodiments, to systems and methods for estimating line width of patterned layers.

### BACKGROUND

Photolithography is a fundamental process in semiconductor manufacturing and microfabrication industries, widely used for defining and transferring intricate patterns onto semiconductor wafers or other substrates. The precise control of line width, i.e., the width of the patterned features, is of paramount importance in ensuring the functionality and performance of semiconductor devices. Various parameters, such as feature size, spacing, and overlay, rely on accurate line width measurements.

Traditional methods of line width measurement in photolithography involve time-consuming and costly processes, often requiring specialized equipment and skilled operators. These methods may include scanning electron microscopy (SEM) or atomic force microscopy (AFM), which provide high accuracy.

### SUMMARY

A method for estimating line width of a patterned layer of a substrate, the method includes generating a light beam using a light source configured to emit a light spectrum including a plurality of wavenumbers. The method further includes exposing the patterned layer of a substrate to the light beam to form a first illuminated area. The method further includes measuring a first spectrum of the first illuminated area using a light detector, the first spectrum including a first variation in light intensity with a wavenumber of the light beam received at the light detector. The method further includes determining a first spectrum area by integrating the first variation in light intensity over a range of the plurality of wavenumbers, the range of the plurality of wavenumbers being selected to match an absorption spectrum of the material of the patterned layer. And the method further includes determining the line width of the patterned layer based on the first spectrum area.

A system for estimating line width of a patterned layer, the system includes a light source that produces a light beam, a set of directional optical components that direct the light beam to a substrate to expose the substrate with the light beam, the substrate loaded in a chuck. The system further includes a scanning optical system configured to scan the light beam across the substrate, a light detector configured to measure a spectrum from a reflected beam generated by reflecting the light beam off of the substrate, and a processor configured to process the spectrum measured by the light detector, and coupled to a memory storing instructions to be executed by the processor. And the system further includes a controller coupled to the memory storing instructions to be executed by the controller, the instructions when executed cause the controller to generate the light beam using the light source configured to emit a light spectrum including a plurality of wavenumbers. The instructions when executed further cause the controller to expose the patterned layer of the substrate to the light beam to form an illuminated area, and measure a spectrum of the illuminated area using the light detector, the spectrum including a variation in light intensity with a wavenumber of the light beam received at the light detector. The instructions when executed further cause the controller to determine a spectrum area by integrating the variation in light intensity over a range of the plurality of wavenumbers, the range of the plurality of wavenumbers being selected to match an absorption spectrum of the material of the patterned layer. And the instructions when executed further cause the controller to determine a line width of the patterned layer based on the spectrum area.

A method for calibrating a system for estimating line width of a patterned layer, the method includes measuring a plurality of line widths at different locations of a calibration wafer including a patterned layer to obtain a map including a plurality of line widths and associated locations. The method further includes measuring a set of spectrums of the patterned layer by exposing the calibration wafer to a light beam, where each spectrum includes a variation in light intensity with a wavenumber of the light beam. The method further includes determining a set of spectrum areas by integrating the variation in light intensity over a range of the plurality of wavenumbers, the range of the plurality of wavenumbers being selected to match an absorption spectrum of the material of the patterned layer. And the method further includes generating a calibration curve by correlating the map with the set of spectrum areas.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flowchart of a method for estimating line width in photolithography in accordance with an embodiment;

FIG. 2 is an illustration of a transmittance spectrum of a typical organic photoresist layer on a substrate over a range of wavenumbers in accordance with an embodiment;

FIGS. 3A-3F are cross-sectional views of a substrate with a photoresist layer illustrating the steps for patterning and estimating line width of the photoresist layer using the method for estimating line width in photolithography of this disclosure in accordance with an embodiment;

FIG. 4 illustrates a system capable of implementing the method for estimating line width in photolithography of this disclosure in accordance with an embodiment;

FIG. 5 is a flowchart of a method for estimating line width in photolithography in accordance with an embodiment;

FIGS. 6A-6B are cross-sectional views of different embodiment calibration wafers capable of being used to calibrate the system to implement the method of estimating line width in photolithography of this disclosure; and

FIG. 7 is a flowchart of a method of calibrating a system to implement the method of estimating line width in photolithography of this disclosure in accordance with an embodiment.

### DETAILED DESCRIPTION OF ILLUSTRATIVE EMBODIMENTS

Photolithography, also known as optical lithography, is a cornerstone technique extensively used in semiconductor device fabrication, where it is utilized to pattern and print micro and nano-scale circuits onto wafer surfaces. It generally involves projecting light through a photomask etched with the circuit pattern onto a photoresist layer of a wafer substrate. The photomask blocks parts of the light to allow the circuit pattern to be replicated on the photoresist layer, which may then be used to etch the features of the circuit pattern in the wafer substrate. The success of this process hinges on the precise measurement of line width to ensure correct and functional patterns (or features) will be created on the wafers.

The process of line width estimation defines the fidelity and quality of the device being fabricated. Currently, these measurements are typically performed using scanning electron microscopy (SEM). However, the use of SEM involves disrupting the manufacturing process due to its invasive nature. The process is time-consuming due to preparation of the sample under investigation, as well as potentially inducing physical and chemical damages to the sample. Moreover, SEM-based measurements often do not provide accurate estimates for smaller line widths, which can lead to sub-optimal performance of the resulting semiconductor devices.

This disclosure presents a system and a method for estimating the line width in photolithography using an absorption spectrum of a patterned layer of a substrate. The system uses a light source to project a light beam on the patterned layer, and collects a reflected beam in a light detector to measure the absorption spectrum. A spectrum area, determined by integrating the absorption spectrum over a range of wavenumbers corresponding to a functional group of the material of the patterned layer, is used to estimate the line width. The spectrum of wavenumbers of the light beam is selected to advantageously target the absorption bands of particular functional groups in the patterned layer. For example, if the patterned layer is an organic photoresist, a spectrum of infrared wavenumbers may be used as the light beam to target C—H bonds in the organic photoresist. The absorption of wavenumbers by a functional group is a function of the volume of material. By using the spectrum area of the absorption spectrum and incorporating predetermined information of the patterned layer (such as the thickness of the layer and the circuit pattern of the photomask), the line width can be estimated.

Through the use of a light beam to efficiently estimate the line width of the patterned layer of the substrate, the systems and methods of this disclosure provide an advantage over traditional methods, as it does not rely on measuring features of the patterned layer directly. Instead, this method estimates line width based on light beam absorption in the patterned layer, eliminating any dependence on the feature size of the circuit pattern. Another advantage of this disclosure is its independence from throughput and lack of reliance on a model for line width estimation. Since this method and system are light based, they can be conveniently integrated into existing systems, such as a photolithography system, to prevent interrupting the manufacturing process. And a key benefit of this disclosure is the method neither chemically nor physically damages the patterned layer of the substrate during line width estimation, demonstrating a significant advantage of this system and method.

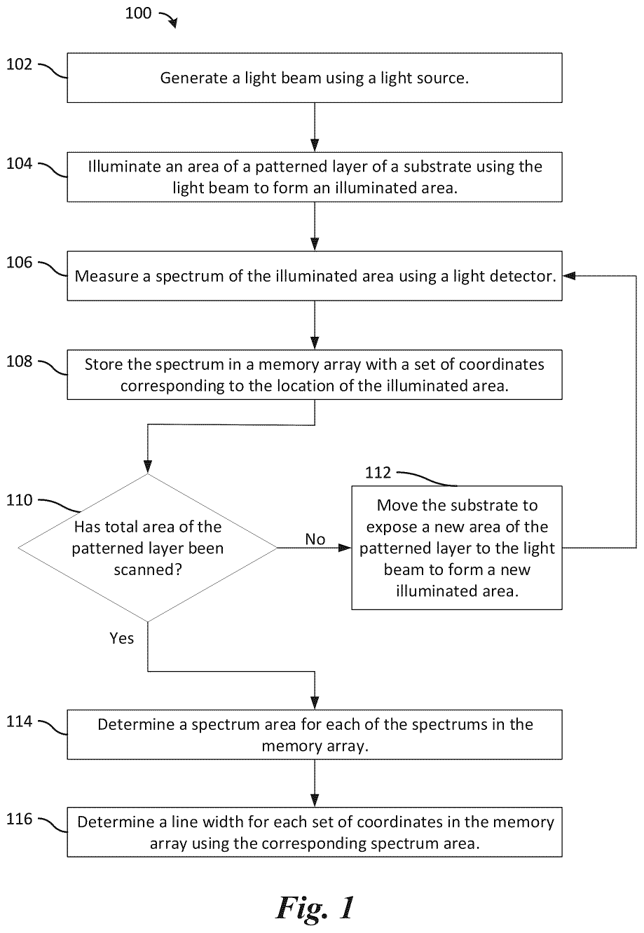

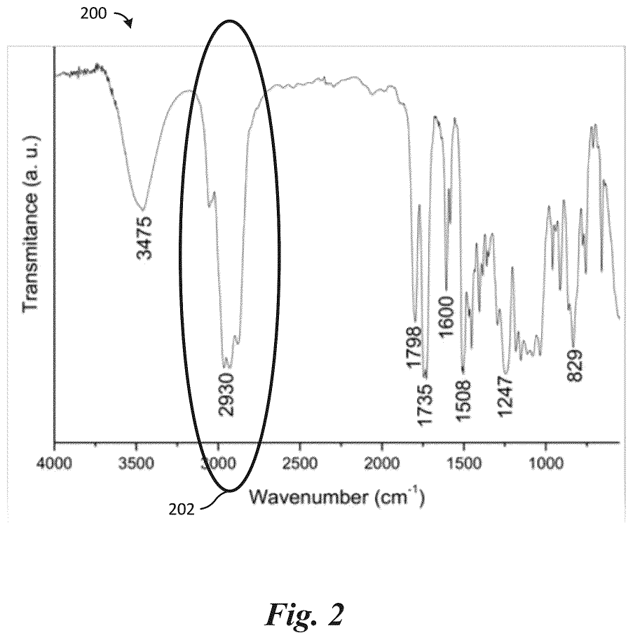

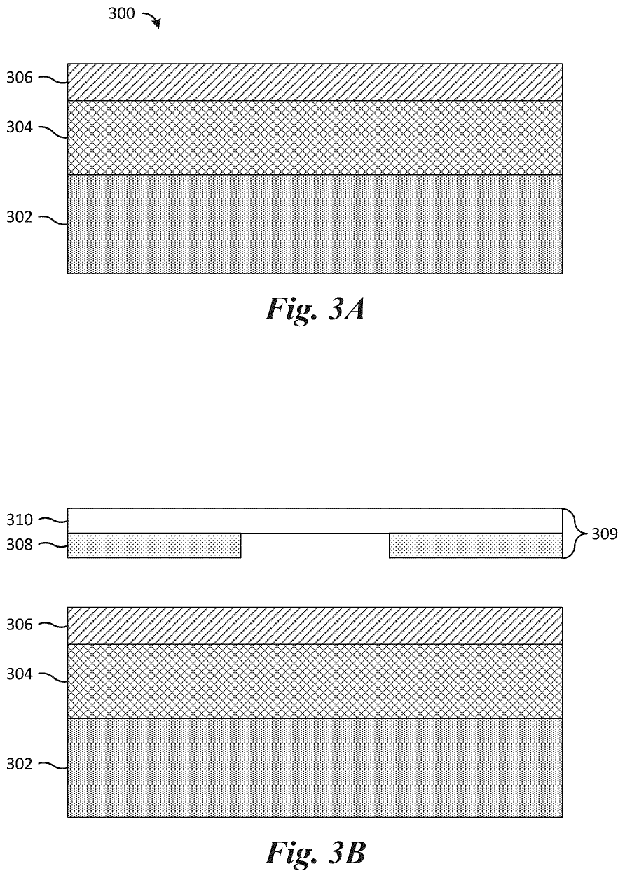

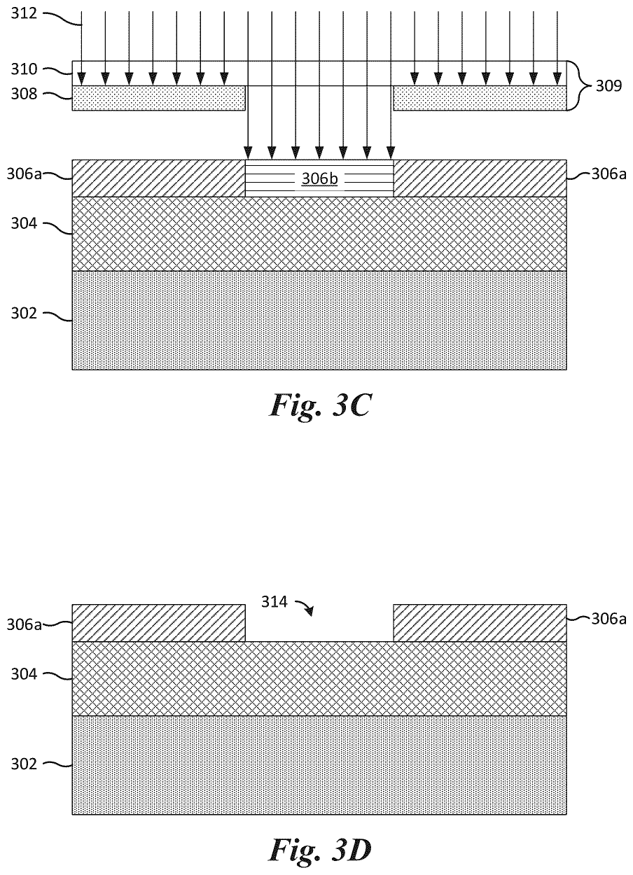

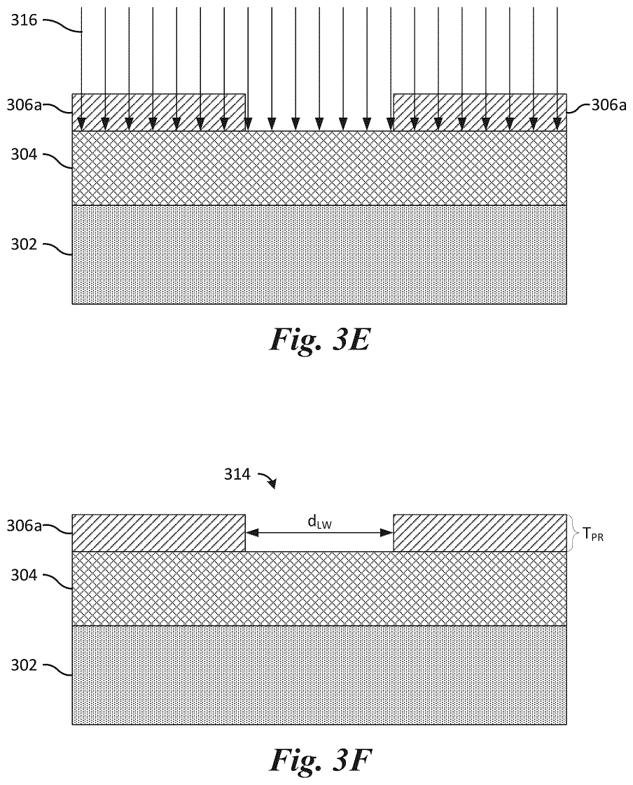

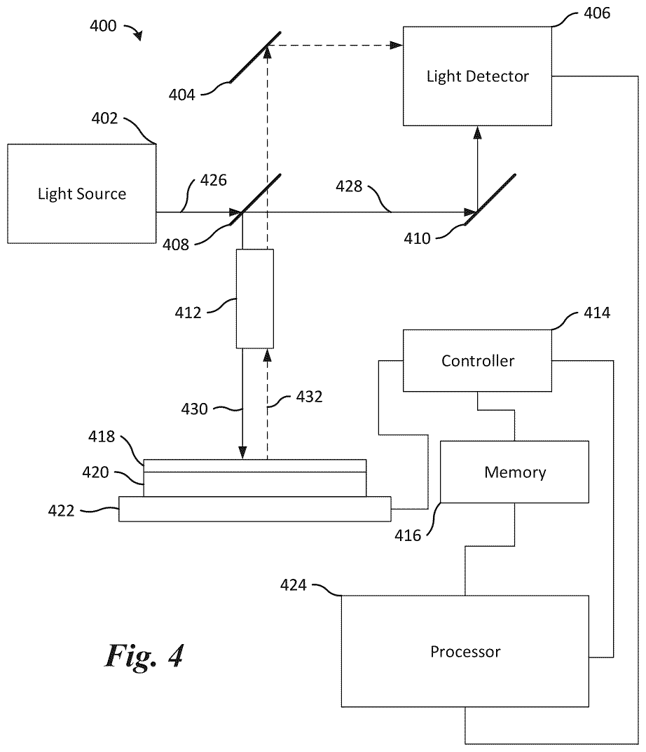

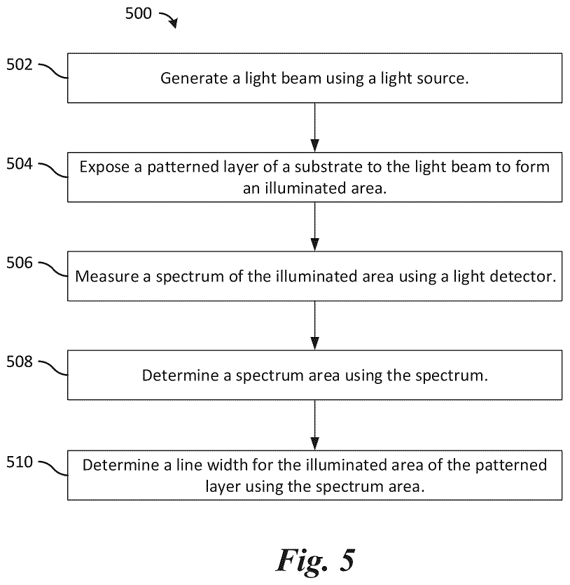

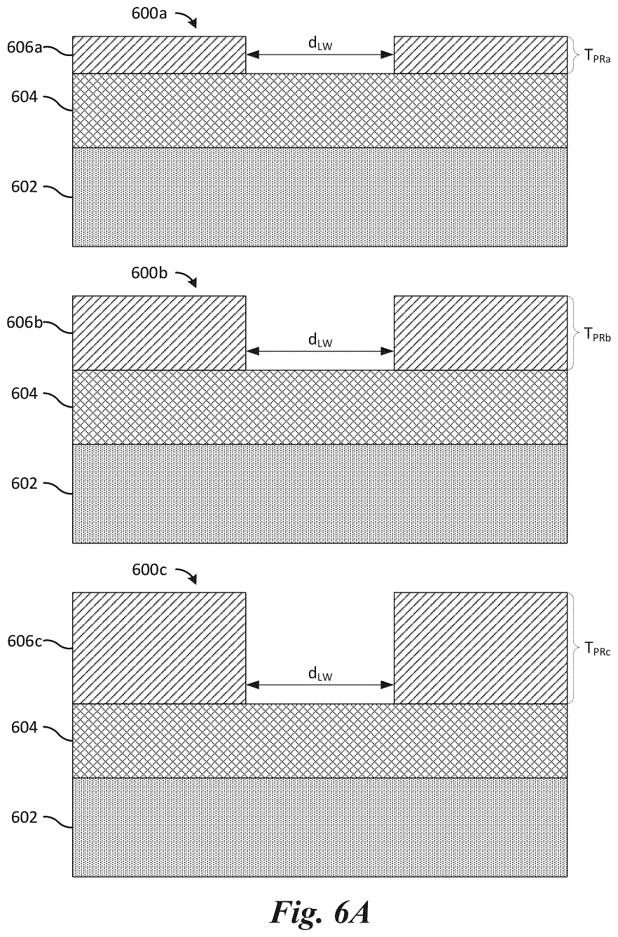

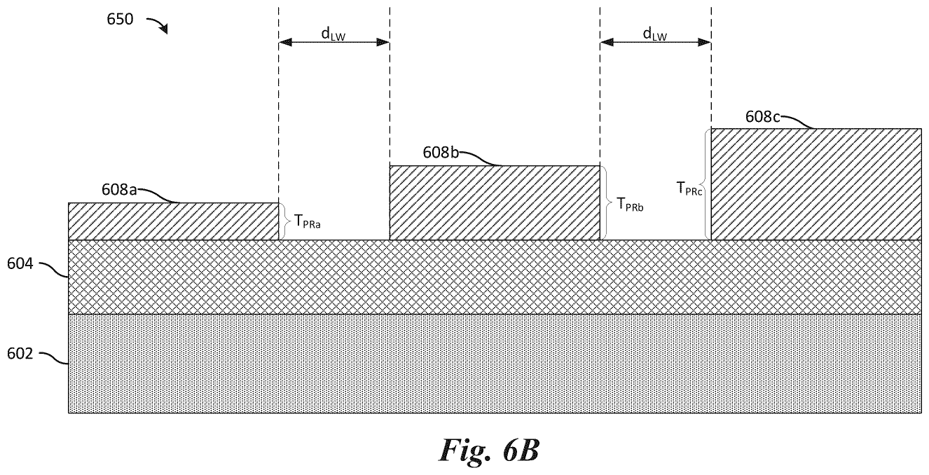

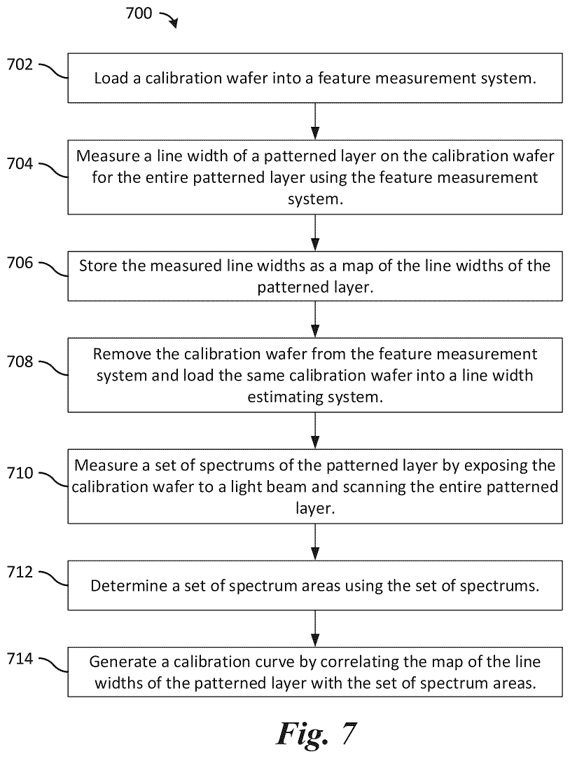

Embodiments provided below describe various systems and methods for estimating line width in photolithography, and in particular, methods using an absorption spectrum collected by a light detector to determine a line width for a patterned layer of a substrate. The following description describes the embodiments. A method for estimating line width in photolithography is described using the flowchart of FIG. 1. An absorption spectrum of a typical organic photoresist used in semiconductor manufacturing is described using the transmittance with respect to wavenumber plot illustrated in FIG. 2. An embodiment process of patterning and subsequently determining the line width of a patterned photoresist layer is described using the cross-sectional views illustrated in FIGS. 3A-3F. A system capable of implementing the method of estimating line width in photolithography is described using the schematic diagram of FIG. 4. Another embodiment method of estimating line width in photolithography is described using FIG. 5. Various embodiments of calibration wafers for the method of estimating line width in photolithography are described using FIGS. 6A-6B. And an embodiment method of calibrating the system for estimating line width in photolithography is described using the flowchart of FIG. 7.

FIG. 1 is a flowchart illustrating a method 100 of estimating line width in photolithography in an embodiment. In box 102, a light beam may be generated by a light source. In an embodiment, the light source may be configured to produce the light beam comprising a plurality of wavenumbers spanning the infrared (IR) light spectrum. In other embodiments, the light source may produce the light beam comprising the plurality of wavenumbers spanning multiple regions of various light spectra, such as IR, visible (VIS), and ultraviolet (UV).

After generating the light beam in box 102, the method 100 illuminates an area of a patterned layer of a substrate using the light beam to form an illuminated area in box 104. In various embodiments, box 104 may be accomplished by using an optical system comprising combinations of lenses, mirrors, and beam splitters to direct the light beam from the light source to the patterned layer. In an embodiment, the light beam passes through the patterned layer, reflects off of an underlying layer of the substrate to produce a reflected beam, which passes back through the patterned layer, and the optical system then directs the reflected beam to a light detector. In other embodiments, the light beam passes through all the layers of the substrate (including perhaps the substrate itself) and then passes through the opposite side of the substrate as a transmitted beam, where another optical system directs the transmitted beam to the light detector.

While propagating through the patterned layer, various wavenumbers of the plurality of wavenumbers of the light beam are absorbed by the patterned layer. The wavenumbers absorbed depend on the composition of the patterned layer (such as the functional groups present). As an example, when the patterned layer is organic photoresist, wavenumbers of about 3000 1/cm of the light beam will be absorbed because of the large quantity of C—H functional groups within the organic photoresist. In various embodiments, the patterned layer of the substrate is some form of organic photoresist, such as diazonaphthoquinone (DNQ), Novolac, PMMA, poly hydroxy styrene (PHST), epoxy, and photoactive compounds (PAC) in a resin or polymer matrix comprising, e.g., phenol-formaldehyde resin. In other embodiments, the patterned layer may be any material suitable as a patterned layer having a carbon back bone.

Once the light detector receives the resulting reflected or transmitted beam, the method 100 proceeds to box 106. In box 106, the method 100 measures a spectrum associated with the illuminated area of the patterned layer of the substrate using the light detector. The spectrum comprises a variation in light intensity with a wavenumber of the light beam received at the light detector, such as the absorption spectrum for a typical organic photoresist used in semiconductor manufacturing illustrated in FIG. 2. In box 108, the method 100 stores the spectrum in a memory array with a set of coordinates corresponding to the location of the illuminated area of the patterned layer.

After storing the spectrum in the memory array with the corresponding set of coordinates, the method 100 checks whether the total area of the patterned layer has been scanned in box 110. If the total area of the patterned layer has not been scanned, the method 100 proceeds to box 112. In box 112, the substrate is moved to expose a new area of the patterned layer to the light beam to form a new illuminated area. In an embodiment, the substrate may be moved by moving a chuck holding the substrate. In other embodiments, rather than moving the substrate, the light beam is moved to form the new illuminated area. After forming the new illuminated area, the method 100 proceeds back to box 106 and follows the steps above until the total area of the patterned layer has been scanned using the light beam.

Back at box 110, if the total area of the patterned layer has been scanned, the method 100 proceeds to box 114. In box 114, the method 100 determines a spectrum area for each of the spectrums stored in the memory array to form a set of spectrum areas. The set of spectrum areas may be stored in the memory array with the corresponding set of coordinates. In order to determine the spectrum area for one of the spectrums, the spectrum is integrated over a range of wavenumbers targeting an absorption wavenumber associated with the functional group of the patterned layer.

Using the spectrum areas determined in box 114, the method 100 determines a line width for each set of coordinates in the memory array in box 116. This may be done using a calibration curve specific to the circuit pattern and thickness of the patterned layer being used in the manufacturing process, where the spectrum area may be correlated with a line width. A benefit of the method 100 is the speed of line width estimation relative to current line width measurement systems. The method 100 of this embodiment can estimate the line width of features in patterned layers faster than current line width measurement systems.

As an example, a transmittance spectrum 200 for typical organic photoresist is illustrated in FIG. 2. The transmittance spectrum 200 plots the transmittance of a typical organic photoresist with the wavenumber of the light beam used to expose the organic photoresist.

The transmittance spectrum 200 may be used to illustrate the absorption of ranges of wavenumbers for different functional groups comprising typical organic photoresist. For example, C—H bonds are associated with the wavenumbers spread peaked around 2930 1/cm. As another example, N—H bonds are associated with the wavenumbers spread peaked around 3475 1/cm. The functional group targeted for determining the line width by the method 100 may be determined based on the transmittance spectrum 200 for typical organic photoresist and a known composition of the patterned layer being scanned using the method of estimating line width in photolithography of this disclosure.

The transmittance spectrum 200 may also be used to determine the range of wavenumbers to integrate over for determining the spectrum area to be used to determine the line width of the patterned layer described in the detailed description of FIG. 1. For example, C—H bonds have a spread of wavenumbers centered on the 2930 1/cm peak where a light beam comprising those wavenumbers will be absorbed. Therefore, a patterned layer comprising organic photoresist with a large number of C—H bonds as functional groups may use a range of wavenumbers containing the 2930 1/cm peak (such as a circled region 202) for determining the spectrum area.

FIGS. 3A-3F are cross-sectional views of a substrate with a photoresist layer illustrating the steps for patterning and subsequently estimating line width of the photoresist layer using the method for estimating line width in photolithography of this disclosure. Illustrated in FIGS. 3A-3F is a layered substrate 300 comprising a substrate 302, a layer stack 304, and a photoresist layer 306 through various steps of the patterning and subsequent method of estimating the line width of this disclosure.

In various embodiments, the substrate 302 may be any material suitable for manufacturing the semiconductor device comprising the circuit pattern to be patterned in the photoresist layer 306, such as a silicon wafer. In similar embodiments, the layer stack 304 may be a stack of alternating layers of material, such as an ONO-stack, or the layer stack 304 may be a single layer of a material. Whichever material comprises the layer stack 304 is specific to the semiconductor device being manufactured. In some embodiments, the layer stack 304 is optional and the photoresist layer 306 is directly on top of the substrate 302. In various embodiments, the photoresist layer 306 may comprise many different photoresist materials, such as organic photoresists with examples including diazonaphthoquinone (DNQ) and photoactive compounds (PAC) in a resin or polymer matrix comprising, e.g., phenol-formaldehyde resin. In other embodiments, the photoresist layer 306 may comprise Novolac, PMMA, poly hydroxy styrene (PHST), epoxy, or any material suitable as a photoresist having a carbon back bone.

The method of estimating line width in photolithography of this disclosure may begin with the layered substrate 300 illustrated in FIG. 3A. The layered substrate 300 comprises the substrate 302, the layer stack 304, and the photoresist layer 306. The step illustrated in FIG. 3A may be the layered substrate loaded in a photolithography system to pattern the photoresist layer 306.

In FIG. 3B, a photomask 309 is aligned over the photoresist layer 306 to pattern the photoresist layer 306 with the circuit pattern of the photomask 309. The photomask 309 comprises a glass layer 310, and a patterned mask layer 308 which are aligned over the photoresist layer 306 to accurately pattern the photoresist layer 306. In an embodiment, the glass layer 310 may be any material the light used for patterning photoresist can pass through. In similar embodiments, the patterned mask layer 308 may be any material the light used for patterning photoresist is not capable of passing through. In those embodiments, the patterned mask layer 308 comprises the circuit pattern to be formed through various manufacturing steps to fabricate a semiconductor structure.

Once the photomask 309 is aligned over the photoresist layer 306, the photolithography system may expose the photoresist layer 306 to an ultraviolet (UV) light beam 312 in FIG. 3C. Illustrated in FIG. 3C, the UV light beam 312 passes through the glass layer 310, but is stopped by the patterned mask layer 308. The UV light beam 312 is allowed to pass through the photomask 309 in regions of the photomask 309 without the patterned mask layer 308. After passing through the regions of the photomask 309 without the patterned mask layer 308, the UV light beam 312 interacts with the photoresist layer 306. By interacting with the photoresist layer 306, the UV light beam 312 activates the regions of the photoresist layer 306 exposed to the UV light beam 312, which forms the patterned photoresist layer 306a (in regions not exposed to the UV light beam 312), and the activated photoresist regions 306b (in regions exposed to the UV light beam 312).

The activated photoresist regions 306b have undergone a chemical change after being exposed to the UV light beam 312. The chemical change enables the activated photoresist regions 306b to be removed by a special solution, typically called developer. Removing the activated photoresist regions 306b leaves the circuit pattern which may be used for processing features into the layered substrate 300.

Removal of the activated photoresist regions 306b using the developer results in the layered substrate 300 of FIG. 3D. The layered substrate 300 of FIG. 3D comprises the substrate 302, the layer stack 304, the patterned photoresist layer 306a, and a feature 314 to be etched into the layer stack 304. A system (such as the system illustrated in FIG. 4) may now use the method of estimating line width in photolithography of this disclosure (described in the detailed description of FIG. 1) to estimate the line width of the feature 314, as well as other properties of the feature 314.

FIG. 3E illustrates a scan of the patterned photoresist layer 306a of the layered substrate 300 of FIG. 3D. A light beam 316 comprising a plurality of wavenumbers incapable of activating the patterned photoresist layer 306a may be used to scan the patterned photoresist layer 306a. The plurality of wavenumbers comprising the light beam 316 are configured such that the light beam 316 reflects off of the surface of the layer stack 304 after passing through the patterned photoresist layer 306a. For example, in various embodiments, the light beam 316 comprises a plurality of wavenumbers spanning the IR spectrum. In an embodiment, FIG. 3E illustrates box 104 of the method 100 illustrated as the flowchart of FIG. 1.

In the embodiment illustrated in FIG. 3E, the light beam 316 may be split (by a beam splitter, for example) such that a first portion is provided to a light detector to measure an initial spectrum. A second portion of the light beam 316 may then be used to form an illuminated area on the layered substrate 300. In regions without the patterned photoresist layer 306a, the light beam 316 reflects off of the surface of the layer stack 304. In regions with the patterned photoresist layer 306a, the light beam 316 passes through the patterned photoresist layer 306a and then reflects off of the surface of the layer stack 304. When the light beam 316 propagates through the patterned photoresist layer 306a, functional groups absorb particular wavenumbers of the plurality of wavenumbers of the light beam 316 which cause variations in spectral intensity over the absorbed wavenumbers. The reflected light beams are provided to the light detector to measure a reflected spectrum. The subtraction of the reflected spectrum from the initial spectrum forms a transmittance spectrum over a range of wavenumbers, such as the transmittance spectrum 200 illustrated in FIG. 2. In an embodiment, FIG. 3E illustrates box 106 of the method 100 illustrated as the flowchart of FIG. 1.

After measuring the transmittance spectrum by scanning the layered substrate 300 with the light beam 316 in FIG. 3E, the line width (d_{LW}) of the feature 314 may be determined. FIG. 3F illustrates the layered substrate 300 after being scanned with the light beam 316. The layered substrate 300 comprises the substrate 302, the layer stack 304, the patterned photoresist layer 306a, and the feature 314. The feature 314 has a line width (d_{LW}) illustrated in FIG. 3F and the patterned photoresist layer 306a has a thickness (T_{PR}). The thickness (T_{PR}) is already known from the photoresist deposition process, and the circuit pattern is also already known from the photomask 309.

A spectrum area of the transmittance spectrum measured in FIG. 3E may be determined using the manner described in the detailed description of FIG. 2, where a range of wavenumbers targeting a particular functional group comprising the patterned photoresist layer 306a are integrated over. The spectrum area, the thickness (T_{PR}), and the circuit pattern located at the coordinates scanned may be used to determine the line width (d_{LW}) of the feature 314 using a calibration curve. In other embodiments, the calibration curve already accounts for the circuit pattern located at the coordinates and the thickness (T_{PR}) such that only the spectrum area is used to determine the line width (d_{LW}). In an embodiment, FIG. 3F illustrates box 114 and box 116 of the method 100 illustrated as the flowchart of FIG. 1. The patterned photoresist layer 306a of FIGS. 3C-3F may be the patterned layer described in the detailed description of the method 100 in FIG. 1.

A key benefit of the method of estimating line width in photolithography of this disclosure is the speed at which the line width measurement may be made. Not only does the method of this disclosure estimate the line width of features faster than conventional techniques, the method may also be used throughout the photolithography process in photolithography systems capable of implementing the method of this disclosure, such as the system illustrated in FIG. 4.

FIG. 4 is a schematic diagram of a system 400 capable of implementing the method of estimating line width in photolithography of this disclosure. The system 400 comprises a light source 402, a first directing mirror 404, a light detector 406, a beam splitter 408, a second directing mirror 410, an objective 412, a controller 414, a memory 416, a processor 424, and a chuck 422. In the embodiment illustrated in FIG. 4, a substrate 420 comprising a patterned layer 418 is loaded in the chuck 422.

The system 400 may use the light source 402 to generate an optical beam 426. In the embodiment illustrated in FIG. 4, the optical beam 426 is directed through the beam splitter 408 to split the optical beam 426 into a reference beam 428 and an incident beam 430. The beam splitter 408 passes the reference beam 428 to the second directing mirror 410 which directs the reference beam 428 to the light detector 406. The beam splitter 408 passes the incident beam 430 through the objective 412 to expose the patterned layer 418 to the incident beam 430 and form an illuminated area. In the embodiment illustrated in FIG. 4, the incident beam 430 is directed at normal incidence to the patterned layer 418. In other embodiments, the system 400 may be configured such that the incident beam 430 has a large angle of incidence to the surface of the patterned layer 418.

After the incident beam 430 passes through the patterned layer 418, the incident beam 430 reflects off of the substrate 420 (or an underlying layer beneath the patterned layer 418) to form the reflected beam 432. The incident beam 430 reflects at normal incidence to the surface of the patterned layer 418, thus the reflected beam 432 propagates back through the patterned layer 418 along the same path the incident beam 430 followed, and passes through the objective 412. After the reflected beam 432 passes through the objective 412, the reflected beam 432 passes through the beam splitter 408 to the first directing mirror 404. The first directing mirror 404 directs the reflected beam 432 to the light detector 406. In the embodiment illustrated in FIG. 4, the beam splitter 408 is designed to allow the reflected beam 432 to propagate through with minimal signal loss.

In the embodiment illustrated in FIG. 4, the controller 414 is electrically coupled to the chuck 422, the memory 416, and the processor 424. The memory 416 is electrically coupled with the controller 414, and the processor 424. The processor 424 is electrically coupled with the memory 416, the controller 414, and the light detector 406. In other embodiments, the controller may also be electrically coupled with the light source 402.

The substrate 420 may be any wafer comprised of a material suitable for manufacturing the semiconductor device, such as a silicon wafer. In various embodiments, the substrate 420 may also have layers between the patterned layer 418 and the substrate 420, such as a layer stack (e.g., an ONO-stack). The patterned layer 418 may be any layer of material that has been patterned according to a circuit pattern to form a semiconductor device, such as a patterned photoresist layer where the photoresist is a typical organic photoresist.

The light source 402 may be any device capable of producing the optical beam 426 comprising a plurality of wavenumbers over the light spectrum. For example, the light source 402 may be a device capable of outputting light beams comprising a plurality of wavenumbers spanning a broad spectrum, such as infrared (IR)-visible (VIS)-ultraviolet (UV). The light source 402 is configured to generate the optical beam 426 based on instructions received from the controller 414. In an embodiment, the optical beam 426 produced by the light source 402 comprises a plurality of wavenumbers from 2500 1/cm to 3150 1/cm. In an embodiment, the light source 402 is a broadband light source such as a continuous wave (CW) broadband light source. For example, the light source 402 may be a laser driven plasma light source (LDLS) that provides light with very high brightness across a broad spectrum UV (ultraviolet)-VIS (visible)-NIR (near infrared)-IR (infrared) (i.e., 190 nm-3500 nm) with a long-life bulb (>9000 hours). In various other embodiments, the light source 402 may be a halogen lamp, some form of LED, or a quantum cascade laser.

The first directing mirror 404 and the second directing mirror 410 may be any reflective device capable of directing the reference beam 428 and the reflected beam 432 to the light detector 406 while minimizing optical aberrations. In one or more embodiments, the first directing mirror 404 and the second directing mirror 410 can be mirror coated with high-reflectance coatings, such as aluminum, gold, or the like. In an embodiment, the first directing mirror 404 and the second directing mirror 410 are 90° off-axis parabolic mirrors.

The light detector 406 may be any device capable of measuring the absorption spectrum of the reflected beam 432 such as a spectrometer, or a dispersion device to split the beam into wavelength components (such as a grating, prism, etcetera) with a sensor array (e.g., CMOS, CCD, or photodiode). In an embodiment, the light detector 406 may comprise two detectors, one for collecting the reference beam 428, and one for collecting the reflected beam 432. In another embodiment, the light detector 406 may be a light detection device with a single input for measuring the reflected beam 432, and receives a set of configuration settings (e.g., in the form of a reference spectrum representing the light spectrum the optical beam 426 comprises) through an electrical coupling with the light source 402. In one embodiment, the light detector 406 may be a dual-channel broad-band high SNR (signal to noise ratio) spectrometer including a measurement channel spectrometer (i.e., measurement spectrometer) for measuring the intensity over wavenumber spectrum of the reflected beam 432 and a reference channel spectrometer (i.e., reference spectrometer) for measuring the intensity over wavenumber spectrum of the reference beam 428.

In another embodiment, the light detector 406 may be a photodiode array, such as an indium arsenide antimonide (InAsSb)-based, transimpedance-amplified photodetector sensitive to light in the MIR spectral range (e.g., from 2700 nm-5300 nm). The light detector 406 is electrically coupled with the processor 424 to send the measured absorption spectrum of the reflected beam 432 for the processor 424 to determine the spectrum area according to the instructions stored in the memory 416.

The beam splitter 408 may be any device capable of splitting the optical beam 426 into the reference beam 428 and the incident beam 430, and designed to allow the reflected beam 432 to propagate through with minimal signal loss. In various embodiments, the beam splitter 408 may be a cube made from two triangular glass prisms, a half-silvered mirror, or a dichroic mirrored prism, or the like.

The controller 414 may be any device capable of implementing the instructions stored in the memory 416 for controlling and operating the system 400 to implement the method of determining line width in photolithography of this disclosure. In the embodiment illustrated in FIG. 4, the controller 414 is electrically coupled with the processor 424, the memory 416, and the chuck 422. The controller 414 is electrically coupled with the chuck 422 to control the positioning of the chuck 422 in the x-y plane to enable the scanning of the patterned layer 418 of the substrate 420 mounted on the chuck 422. The controller 414 is electrically coupled with the memory 416 to execute the method for estimating line width in photolithography of this disclosure stored in the memory 416 as a set of instructions. And the controller 414 is electrically coupled with the processor 424 to control the processor 424 to determine the line width. In other embodiments, the controller 414 may also be electrically coupled with the light source 402 to control the generation of the optical beam 426 and configure the spectral settings of the optical beam 426.

The memory 416 may be any device suitable for storing instructions to be executed by the controller 414 and storing instructions to be executed by the processor 424. Further, the memory 416 may be any device suitable for storing the processed data (e.g., spectrum areas and coordinates, or line widths and coordinates, or calibration curve, etcetera), storing the information about the patterned layer 418 (e.g., layer thickness and circuit pattern), and storing the instructions, such as RAM, ROM, PROM, EPROM, EEPROM, hard disk, or any other information processing device with which the controller 414 communicates, such as a server or computer (or even the processor 424 in an embodiment).

In the embodiment illustrated in FIG. 4, the memory 416 is electrically coupled with the processor 424 to store the measured spectrums of the reflected beam 432 measured by the light detector 406, to provide the instructions to the processor 424 for determining the spectrum area of the measured spectrums of the reflected beam 432, and to store the calibration curve for the processor 424 to reference to determine the line width based on the spectrum area. In the same embodiment, the memory 416 is also electrically coupled with the controller 414 to provide instructions for the operation and control of the system 400 by the controller 414.

The chuck 422 may be any device capable of holding the substrate 420, and moving in the x-y plane in response to instructions received from the controller 414. In an embodiment, the chuck 422 may be a vacuum chuck. A vacuum chuck may hold the substrate 420 by using a vacuum to pump the air out of cavities located behind the vacuum chuck so that air pressure will hold the substrate 420 in place. In the embodiment illustrated in FIG. 4, the objective 412 is fixed in place, thus the scanning of the patterned layer 418 on the substrate 420 is accomplished by moving the chuck 422 in the x-y plane according to the instructions from the controller 414. In other embodiments, the objective 412 may be attached to a moveable mount to enable the scanning of the substrate 420 to be performed by the controller 414 instructing the moveable mount to move the objective 412 across the patterned layer 418. In various embodiments, the objective 412 may be any suitable optical device for projecting the incident beam 430 and receiving the reflected beam 432, such as a lens, or a lens system.

The processor 424 may be any device capable of performing the processing for the method of determining line width in photolithography that the system 400 is implementing. For example, the processor 424 may be a computer configured to determine the spectrum area and subsequently determine the line width of the patterned layer 418 (using the calibration curve and information about the patterned layer) based on the measured spectrum from the light detector 406 by executing instructions stored in the memory 416. In the embodiment illustrated in FIG. 4, the processor 424 is electrically coupled with the memory 416 and the light detector 406. The processor 424 is electrically coupled with the light detector 406 to receive the measured spectrums of the reflected beam 432. And the processor 424 is electrically coupled with the memory 416 to execute the instructions for determining the line width, referencing information about the patterned layer (such as layer thickness and circuit pattern), and storing the values determined by the processor 424 (such as line width and spectrum area).

The system 400 of FIG. 4 is capable of implementing the method of estimating line width in photolithography of this disclosure described using FIG. 1. The system 400 of FIG. 4 is also capable of implementing other embodiment methods of estimating line width in photolithography, such as the method illustrated as the flowchart of FIG. 5.

Another embodiment method for estimating line width in photolithography is illustrated as a method 500 in FIG. 5. In box 502, the method 500 generates a light beam using a light source, such as the light source 402 of FIG. 4. The light beam exposes a patterned layer of a substrate to form an illuminated area in box 504. The method 500 measures a spectrum of the illuminated area using a light detector in box 506. For example, the light detector may be the light detector 406 illustrated in FIG. 4.

After measuring the spectrum of the illuminated area in box 506, the method 500 proceeds to box 508. In box 508, the method 500 determines a spectrum area using the spectrum measured by the light detector. For example, the spectrum area may be determined by integrating the transmittance spectrum 200 of FIG. 2 over the range of wavenumbers in the circled region 202 in an embodiment where the patterned layer comprises a material with a large number of C—H bonds as functional groups.

Once the spectrum area is determined, the method 500 proceeds to box 510. In box 510, the method 500 determines a line width for the illuminated area of the patterned layer using the spectrum area. In an embodiment, the line width is determined by correlating the spectrum area with a line width using a calibration curve specific to the feature recipe of the patterned layer.

In another embodiment, a simpler technique may advantageously be used in situations when the same features are being formed in the illuminated area and the pitch of the features being formed is known (from the mask design, for example). For an array of lines designed at a constant pitch, the critical dimension of the features can be estimated from the fraction of opening or gap between adjacent features. The fraction of openings can be determined by comparing the spectrum of an unpatterned layer to a patterned layer comprising the features. As an example, the line width may be determined by using a pattern pitch specific to the feature recipe in the illuminated area, a second spectrum area of the patterned layer before it was patterned, and the spectrum area of the patterned layer. The second spectrum area may be determined by the same method used to find the spectrum area of the patterned layer, but the illuminated area is formed on an unpatterned layer, where the unpatterned layer is the patterned layer before being patterned. A ratio may be determined by dividing the spectrum area of the patterned layer by the second spectrum area of the patterned layer before it was patterned. The line width may be calculated by multiplying the pattern pitch with the ratio of the spectrum area with the second spectrum area. Using the ratio, the method of determining line width may distinguish between feature recipes with the same pattern pitch, but different line widths.

In reference to both embodiment methods of estimating line width in photolithography described in FIG. 1 and FIG. 5, another benefit of the method of this disclosure is the line width of patterned layers may be determined without using a model. The method of this disclosure uses a calibration curve to determine line width based on a measured spectrum area (where the spectrum area can be correlated with a volume of material comprising the patterned layer, and combining the known circuit pattern of features, the line width may be estimated). Therefore, another benefit of the method of this disclosure is the line width may be estimated without accounting for throughput or a dependence on feature size of the patterned layer. The measurement of the line width using the method of this disclosure does not depend on feature size because the measurement uses light to determine the volume of material present (the absorption, or spectrum area) as opposed to conventional methods of estimating line width which directly measure the patterned features (which imposes a dependence on feature size).

The embodiment methods of estimating line width in photolithography of this disclosure use a calibration curve to determine the line width of features in the patterned layer. Thus, calibration wafers may be used to determine the calibration curve for determining line width from the spectrum area based on the circuit pattern (such as pattern pitch) and thickness of the patterned layer (which are known according to the manufacturing recipe of the semiconductor device). FIGS. 6A-6B illustrate calibration wafers in various embodiments capable of being used to calibrate the system to estimate line width in photolithography of this disclosure. The illustrations of FIGS. 6A-6B are cross-sectional views of the calibration wafers and it is implied to not have a hard termination at the left and right edges, but to continue the pattern left and right.

FIG. 6A illustrates an embodiment of a plurality of calibration wafers (600a-600c) used to calibrate the system to estimate line width in photolithography of this disclosure. For each circuit pattern to have the line width estimated, a plurality of calibration wafers (600a-600c) comprising a variety of different patterned layer thicknesses (T_{PRa}-T_{PRc}) may be used to calibrate the system. A patterned layer with line width (d_{LW}) is illustrated in each patterned layer of the plurality of calibration wafers (600a-600c) and is the same across the plurality of patterned layer thicknesses.

The plurality of calibration wafers of FIG. 6A comprises a first calibration wafer 600a, a second calibration wafer 600b, and a third calibration wafer 600c. In other embodiments, more than three calibration wafers may be used. In further embodiments, less than three calibration wafers may be used. Each of the plurality of calibration wafers of FIG. 6A comprise a substrate 602 with a layer stack 604. In various embodiments, the substrate 602 and the layer stack 604 may be comprised of the same materials detailed above for FIG. 3A.

The first calibration wafer 600a further comprises a first patterned layer 606a of patterned layer thickness (T_{PRa}). The second calibration wafer 600b further comprises a second patterned layer 606b of patterned layer thickness (T_{PRb}), which is larger than (T_{PRa}). And the third calibration wafer 600c further comprises a third patterned layer 606c of patterned layer thickness (T_{PRc}), which is larger than both T_{PRa} and T_{PRb}. Each of the patterned layers of the plurality of calibration wafers (600a-600c) comprise the same materials and have been patterned with the same circuit pattern. Each of the patterned layers of the plurality of calibration wafers comprise the same material and are the material to be used according to the manufacturing recipe to manufacture the semiconductor device.

Because the absorption of the light beam as it propagates through a patterned layer is a function of the volume of material, calibration wafers (600a-600c) are prepared with a variety of thicknesses so a calibration curve may be determined to correlate the different volume of material (or measured spectrum area) of the patterned layer with a line width based on the circuit pattern and thickness of the patterned layer. The system for estimating line width in photolithography of this disclosure will be recalibrated for every different circuit pattern used, and each calibration for a new circuit pattern will use a plurality of calibration wafers fabricated specifically for calibrating the system for that particular circuit pattern.

In other words, a calibration curve for each circuit pattern of a patterned layer would optimize the performance of the line width estimation of this disclosure. A system, such as the system 400 of FIG. 4, can use the calibration wafers (600a-600c) to generate a calibration curve by measuring the calibration wafers (600a-600c) (for the variety in thicknesses of the particular circuit pattern the patterned layers were patterned with) according to the calibration method of FIG. 7.

FIG. 6B illustrates an embodiment of calibration wafer 650 used to calibrate the system to estimate line width in photolithography of this disclosure. The calibration wafer 650 comprises a patterned layer (608a-608c) of a circuit pattern of repeating features of various different patterned layer thickness (T_{PRa}-T_{PRc}) (one thickness per circuit pattern before the features repeat on the substrate 602), the substrate 602, and the layer stack 604. A line width (d_{LW}) is illustrated in the patterned layer (608a-608c) and is the same across the substrate 602 for the particular circuit pattern used. The difference between the calibration wafer 650 of FIG. 6B from the plurality of calibration wafers (600a-600c) of FIG. 6A, is the calibration wafer 650 uses a single calibration wafer that has a variety of patterned layer thicknesses (T_{PRa}-T_{PRc}) rather than using a plurality of calibration wafers, each of a different patterned layer thickness. The patterned layers of FIGS. 6A-6B may comprise the same materials described above for FIG. 3A, such as organic photoresist. In an embodiment, the patterning of the patterned layer (608a-608c) may comprise many features of different line widths (d_{LW}).

Any of the embodiments of the calibration wafers illustrated in FIGS. 6A-6B may be used in a calibration method to calibrate the system to estimate line width in photolithography of this disclosure. For example, the calibration wafers illustrated in FIGS. 6A-6B may be used in the calibration method illustrated in the flowchart of FIG. 7 and described below.

FIG. 7 is a flowchart of a method of calibrating a system to implement the method of estimating line width in photolithography of this disclosure. In box 702, a calibration method 700 loads a calibration wafer (such as the calibration wafers detailed using FIGS. 6A-6B) into a feature measurement system. The feature measurement system may be any feature measurement system that is not the system of this disclosure and that does not damage the calibration wafers during the process of measuring line width. In an embodiment, the feature measurement system may be an atomic force microscope (AFM).

After loading the calibration wafer in the feature measurement system, the calibration method 700 proceeds to box 704. In box 704, the calibration method 700 measures a line width of a patterned layer on the calibration wafer for the entire patterned layer using the feature measurement system. The calibration method 700 stores the measured line widths as a map of the line widths of the patterned layer in box 706.

Once the map of line widths has been stored in box 706, the calibration method proceeds to box 708. In box 708, the calibration method 700 removes the calibration wafer from the feature measurement system and loads the same calibration wafer into a line width estimating system of this disclosure. In box 710, the line width estimating system of this disclosure may be used to measure a set of spectrums of the patterned layer of the calibration wafer. The set of spectrums may be measured by exposing the calibration wafer to a light beam, scanning the entire patterned layer, and collecting the spectrums using a light detector. For example, the light beam may be produced by a light source such as the light source 402 of FIG. 4 and the light detector may be the light detector 406 of FIG. 4.

In box 712, the calibration method 700 determines a set of spectrum areas using the set of spectrums measured in box 710. Each of the set of spectrum areas may be determined using the process described in the detailed description of FIG. 2, where each of the set of spectrums is integrated over a range of wavenumbers. And, after the set of spectrum areas has been determined, the calibration method 700 proceeds to box 714. In box 714, the calibration method 700 generates a calibration curve to be used for a particular process recipe (where the process recipe comprises the circuit pattern to be formed on layered substrates). The calibration curve may be generated by correlating the map of the line widths of the patterned layer determined by the feature measurement system with the set of spectrum areas determined in box 712.

Example embodiments of the invention are described below. Other embodiments can also be understood from the entirety of the specification as well as the claims filed herein.

Example 1. A method for estimating line width of a patterned layer of a substrate, the method includes generating a light beam using a light source configured to emit a light spectrum including a plurality of wavenumbers. The method further includes exposing the patterned layer of a substrate to the light beam to form a first illuminated area. The method further includes measuring a first spectrum of the first illuminated area using a light detector, the first spectrum including a first variation in light intensity with a wavenumber of the light beam received at the light detector. The method further includes determining a first spectrum area by integrating the first variation in light intensity over a range of the plurality of wavenumbers, the range of the plurality of wavenumbers being selected to match an absorption spectrum of the material of the patterned layer. And the method further includes determining the line width of the patterned layer based on the first spectrum area.

Example 2. The method of example 1, further includes exposing the layer of the substrate before being patterned, the layer being exposed to the light beam to form a second illuminated area. And the method further includes where the patterned layer includes a plurality of features having a first pitch, and where determining the line width includes determining a second spectrum area of the layer before being patterned, the second spectrum area being determined over the second illuminated area using the light detector and including a second variation in light intensity with a wavenumber of the light beam received at the light detector integrated over the range of the plurality of wavenumbers. And the determining the line width further includes determining a ratio of the first spectrum area with the second spectrum area, and determining the line width of the plurality of features based on the ratio, and the first pitch.

Example 3. The method of one of examples 1 or 2, further includes moving the location of the first illuminated area on the patterned layer to form a new illuminated area. The method further includes measuring a new spectrum of the new illuminated area using the light detector, determining a new spectrum area of the patterned layer of the substrate, and determining a new line width of the patterned layer based on the new spectrum area. And the method further includes repeating the process above until the entire surface of the patterned layer has been scanned.

Example 4. The method of one of examples 1 to 3, where the patterned layer is a patterned photoresist layer including C—H bonds, such as DNQ, Novolac, PMMA, PHST (poly hydroxy styrene), or epoxy.

Example 5. The method of one of examples 1 to 4, where the range of the plurality of wavenumbers target the absorption wavenumber 3000 1/cm of C—H bonds in the patterned photoresist layer.

Example 6. The method of one of examples 1 to 5, where the range of the plurality of wavenumbers target the absorption wavenumber of the type of bonds present in the material of the patterned layer.

Example 7. The method of one of examples 1 to 6, where the determining of the line width includes using a calibration curve correlating the first spectrum area and the line width.

Example 8. A system for estimating line width of a patterned layer, the system includes a light source that produces a light beam, a set of directional optical components that direct the light beam to a substrate to expose the substrate with the light beam, the substrate loaded in a chuck. The system further includes a scanning optical system configured to scan the light beam across the substrate, a light detector configured to measure a spectrum from a reflected beam generated by reflecting the light beam off of the substrate, and a processor configured to process the spectrum measured by the light detector, and coupled to a memory storing instructions to be executed by the processor. And the system further includes a controller coupled to the memory storing instructions to be executed by the controller, the instructions when executed cause the controller to generate the light beam using the light source configured to emit a light spectrum including a plurality of wavenumbers. The instructions when executed further cause the controller to expose the patterned layer of the substrate to the light beam to form an illuminated area, and measure a spectrum of the illuminated area using the light detector, the spectrum including a variation in light intensity with a wavenumber of the light beam received at the light detector. The instructions when executed further cause the controller to determine a spectrum area by integrating the variation in light intensity over a range of the plurality of wavenumbers, the range of the plurality of wavenumbers being selected to match an absorption spectrum of the material of the patterned layer. And the instructions when executed further cause the controller to determine a line width of the patterned layer based on the spectrum area.

Example 9. The system of example 8, where the instructions when executed further cause the controller to move the location of the illuminated area on the patterned layer to form a new illuminated area by moving the chuck. The instructions when executed further cause the controller to measure a new spectrum of the new illuminated area using the light detector, and determine a new spectrum area of the patterned layer of the substrate. The instructions when executed further cause the controller to determine a new line width of the patterned layer based on the new spectrum area. And the instructions when executed further cause the controller to repeat the process above until the entire surface of the patterned layer has been scanned.

Example 10. The system of one of examples 8 or 9, where the light detector is a photodiode array.

Example 11. The system of one of examples 8 to 10, where the patterned layer is a patterned photoresist layer including C—H bonds, such as DNQ, Novolac, PMMA, PHST (poly hydroxy styrene), or epoxy.

Example 12. The system of one of examples 8 to 11, where the range of the plurality of wavenumbers target the absorption wavenumber 3000 1/cm of C—H bonds in the patterned photoresist layer.

Example 13. The system of one of examples 8 to 12, where the range of the plurality of wavenumbers target the absorption wavenumber of the type of bonds present in the material of the patterned layer.

Example 14. The system of one of examples 8 to 13, where the light detector is a spectrometer.

Example 15. A method for calibrating a system for estimating line width of a patterned layer, the method includes measuring a plurality of line widths at different locations of a calibration wafer including a patterned layer to obtain a map including a plurality of line widths and associated locations. The method further includes measuring a set of spectrums of the patterned layer by exposing the calibration wafer to a light beam, where each spectrum includes a variation in light intensity with a wavenumber of the light beam. The method further includes determining a set of spectrum areas by integrating the variation in light intensity over a range of the plurality of wavenumbers, the range of the plurality of wavenumbers being selected to match an absorption spectrum of the material of the patterned layer. And the method further includes generating a calibration curve by correlating the map with the set of spectrum areas.

Example 16. The method of example 15, where the patterned layer includes a patterned photoresist layer including C—H bonds.

Example 17. The method of one of examples 15 or 16, where the measuring the plurality of line widths is performed using a scanning electron microscope (SEM), or an atomic force microscope (AFM).

Example 18. The method of one of examples 15 to 17, further includes measuring a spectrum of a patterned layer of a subsequent wafer being processed by exposing the subsequent wafer to the light beam. And the method further includes comparing the spectrum of the patterned layer of the subsequent wafer with the calibration curve to determine a critical dimension of features of the patterned layer.

Example 19. The method of one of examples 15 to 18, where the range of the plurality of wavenumbers target the absorption wavenumber 3000 1/cm of C—H bonds.

Example 20. The method of one of examples 15 to 19, where the map of the line widths of the patterned layer includes the measured line widths with the coordinates of the location of the measured line widths.

Example 21. The method of one of examples 15 to 20, where the patterned layer includes a patterned photoresist layer, and where the range of the plurality of wavenumbers target the absorption wavenumber of the bonds for the patterned photoresist layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for estimating line width of a patterned layer of a substrate, the method comprising:
generating a light beam using a light source configured to emit a light spectrum comprising a plurality of wavenumbers;
exposing the patterned layer of a substrate to the light beam to form a first illuminated area;
measuring a first spectrum of the first illuminated area using a light detector, the first spectrum comprising a first variation in light intensity with a wavenumber of the light beam received at the light detector;
determining a first spectrum area by integrating the first variation in light intensity over a range of the plurality of wavenumbers, the range of the plurality of wavenumbers being selected to match an absorption spectrum of the material of the patterned layer; and
determining the line width of the patterned layer based on the first spectrum area.

2. The method of claim 1, further comprising:
exposing the layer of the substrate before being patterned, the layer being exposed to the light beam to form a second illuminated area; and
wherein the patterned layer comprises a plurality of features having a first pitch, and
wherein determining the line width comprises
determining a second spectrum area of the layer before being patterned, the second spectrum area being determined over the second illuminated area using the light detector and comprising a second variation in light intensity with a wavenumber of the light beam received at the light detector integrated over the range of the plurality of wavenumbers,
determining a ratio of the first spectrum area with the second spectrum area, and
determining the line width of the plurality of features based on the ratio, and the first pitch.

3. The method of claim 1, further comprising:
moving the location of the first illuminated area on the patterned layer to form a new illuminated area;
measuring a new spectrum of the new illuminated area using the light detector;
determining a new spectrum area of the patterned layer of the substrate;
determining a new line width of the patterned layer based on the new spectrum area; and
repeating the process above until the entire surface of the patterned layer has been scanned.

4. The method of claim 1, wherein the patterned layer is a patterned photoresist layer comprising C—H bonds, such as DNQ, Novolac, PMMA, PHST (poly hydroxy styrene), or epoxy.

5. The method of claim 4, wherein the range of the plurality of wavenumbers target the absorption wavenumber 3000 1/cm of C—H bonds in the patterned photoresist layer.

6. The method of claim 1, wherein the range of the plurality of wavenumbers target the absorption wavenumber of the type of bonds present in the material of the patterned layer.

7. The method of claim 1, wherein the determining of the line width comprises using a calibration curve correlating the first spectrum area and the line width.

8. A system for estimating line width of a patterned layer, the system comprising:
a light source that produces a light beam;
a set of directional optical components that direct the light beam to a substrate to expose the substrate with the light beam, the substrate loaded in a chuck;
a scanning optical system configured to scan the light beam across the substrate;
a light detector configured to measure a spectrum from a reflected beam generated by reflecting the light beam off of the substrate;
a processor configured to process the spectrum measured by the light detector, and coupled to a memory storing instructions to be executed by the processor; and
a controller coupled to the memory storing instructions to be executed by the controller, the instructions when executed cause the controller to:
generate the light beam using the light source configured to emit a light spectrum comprising a plurality of wavenumbers;
expose the patterned layer of the substrate to the light beam to form an illuminated area;
measure a spectrum of the illuminated area using the light detector, the spectrum comprising a variation in light intensity with a wavenumber of the light beam received at the light detector;
determine a spectrum area by integrating the variation in light intensity over a range of the plurality of wavenumbers, the range of the plurality of wavenumbers being selected to match an absorption spectrum of the material of the patterned layer; and
determine a line width of the patterned layer based on the spectrum area.

9. The system of claim 8, wherein the instructions when executed further cause the controller to:
move the location of the illuminated area on the patterned layer to form a new illuminated area by moving the chuck;
measure a new spectrum of the new illuminated area using the light detector;
determine a new spectrum area of the patterned layer of the substrate;
determine a new line width of the patterned layer based on the new spectrum area; and
repeat the process above until the entire surface of the patterned layer has been scanned.

10. The system of claim 8, wherein the light detector is a photodiode array.

11. The system of claim 8, wherein the patterned layer is a patterned photoresist layer comprising C—H bonds, such as DNQ, Novolac, PMMA, PHST (poly hydroxy styrene), or epoxy.

12. The system of claim 11, wherein the range of the plurality of wavenumbers target the absorption wavenumber 3000 1/cm of C—H bonds in the patterned photoresist layer.

13. The system of claim 8, wherein the range of the plurality of wavenumbers target the absorption wavenumber of the type of bonds present in the material of the patterned layer.

14. The system of claim 8, wherein the light detector is a spectrometer.

15. A method for calibrating a system for estimating line width of a patterned layer, the method comprising:
measuring a plurality of line widths at different locations of a calibration wafer comprising a patterned layer to obtain a map comprising a plurality of line widths and associated locations;
measuring a set of spectrums of the patterned layer by exposing the calibration wafer to a light beam, wherein each spectrum comprises a variation in light intensity with a wavenumber of the light beam;
determining a set of spectrum areas by integrating the variation in light intensity over a range of the plurality of wavenumbers, the range of the plurality of wavenumbers being selected to match an absorption spectrum of the material of the patterned layer; and
generating a calibration curve by correlating the map with the set of spectrum areas.

16. The method of claim 15, wherein the patterned layer comprises a patterned photoresist layer comprising C—H bonds.

17. The method of claim 15, wherein the measuring the plurality of line widths is performed using a scanning electron microscope (SEM), or an atomic force microscope (AFM).

18. The method of claim 15, further comprising:
measuring a spectrum of a patterned layer of a subsequent wafer being processed by exposing the subsequent wafer to the light beam; and
comparing the spectrum of the patterned layer of the subsequent wafer with the calibration curve to determine a critical dimension of features of the patterned layer.

19. The method of claim 16, wherein the range of the plurality of wavenumbers target the absorption wavenumber 3000 1/cm of C—H bonds.

20. The method of claim 15, wherein the map of the line widths of the patterned layer comprises the measured line widths with the coordinates of the location of the measured line widths.

21. The method of claim 15, wherein the patterned layer comprises a patterned photoresist layer, and wherein the range of the plurality of wavenumbers target the absorption wavenumber of the bonds for the patterned photoresist layer.
